(19) United States
(12) Patent Application Publication
(10) Pub. No.: US 2017/0345942 A1
(43) Pub. Date: Nov. 30, 2017

(54) THIN-FILM TRANSISTOR, DISPLAY UNIT, AND ELECTRONIC APPARATUS

(71) Applicant: JOLED INC., Tokyo (JP)

(72) Inventors: Tomoatsu KINOSHITA, Tokyo (JP); Yuichiro ISHIYAMA, Tokyo (JP)

(21) Appl. No.: 15/584,008

(22) Filed: May 1, 2017

(30) Foreign Application Priority Data
May 26, 2016 (JP) 2016-105264

(51) Int. Cl. H01L 29/786; H01L 27/12; H01L 51/00; G02F 1/1368; H01L 27/32; G02F 1/1333

(52) U.S. Cl. CPC H01L 29/78603; H01L 27/1225; H01L 27/1218; H01L 29/7869; G02F 1/133305; G02F 1/1368; H01L 27/3262; G02F 2001/13685; H01L 51/0097

(57) ABSTRACT

A thin-film transistor includes a resin substrate and a thin-film transistor layer. The resin substrate has flexibility, and has volume resistivity of equal to or greater than 1×10¹⁷ Ω·cm. The thin-film transistor layer is provided on the resin substrate.

### CROSS REFERENCE TO RELATED APPLICATIONS

This application claims the benefit of Japanese Priority Patent Application JP2016-105264 filed May 26, 2016, the entire contents of which are incorporated herein by reference.

### BACKGROUND

The disclosure relates to a thin-film transistor that utilizes a resin substrate having flexibility, and to a display unit and an electronic apparatus each including the thin-film transistor.

Various proposals have been made on a flexible device in which various element layers are formed on a flexible substrate such as a plastic substrate and a resin substrate. For example, reference is made to Japanese Unexamined Patent Application Publication No. 2003-209257. Non-limiting examples of the device layer may include a thin-film transistor (TFT) layer.

### SUMMARY

In general, it is desirable that a flexible device have increased reliability.

It is desirable to provide a thin-film transistor, a display unit, and an electronic apparatus that are able to increase reliability.

A thin-film transistor according to an embodiment of the disclosure includes: a resin substrate having flexibility, and having volume resistivity of equal to or greater than 1×10¹⁷ Ω·cm; and a thin-film transistor layer provided on the resin substrate.

A display unit according to an embodiment of the disclosure is provided with a thin-film transistor and a display element layer. The thin-film transistor includes: a resin substrate having flexibility, and having volume resistivity of equal to or greater than 1×10¹⁷ Ω·cm; and a thin-film transistor layer provided on the resin substrate.

An electronic apparatus according to an embodiment of the disclosure is provided with one of a display unit and an imaging unit. The display unit and the imaging unit are each provided with a thin-film transistor. The thin-film transistor includes: a resin substrate having flexibility, and having volume resistivity of equal to or greater than 1×10¹⁷ Ω·cm; and a thin-film transistor layer provided on the resin substrate.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a schematic cross-sectional view of an example of an overall configuration of a display unit that includes a thin-film transistor according to an embodiment of the disclosure.

FIG. 2 is an explanatory, schematic cross-sectional view of a support substrate used upon manufacturing of the display unit illustrated in FIG. 1.

FIG. 3 is a characteristic diagram illustrating an example of a relationship between volume resistivity of a resin substrate illustrated in FIGS. 1 and 2 and a variation in threshold voltage, i.e., TFT reliability, of the thin-film transistor.

FIG. 4 is a schematic cross-sectional view of an example of an overall configuration of a display unit that includes a thin-film transistor according to a first comparative example.

FIG. 5 is a characteristic diagram illustrating an example of a relationship between stress time and a variation in threshold voltage of the thin-film transistor according to each of the first comparative example illustrated in FIG. 4 and a second comparative example.

FIG. 6 is a block diagram illustrating an example of an overall configuration of a display unit that includes the thin-film transistor illustrated in FIG. 1.

FIG. 7 is a block diagram illustrating an example of an overall configuration of an imaging unit that includes the thin-film transistor illustrated in FIG. 1.

FIG. 8 is a block diagram illustrating an electronic apparatus that includes one of the display unit illustrated in FIG. 6 and the imaging unit illustrated in FIG. 7 according to an application example.

### DETAILED DESCRIPTION

In the following, some example embodiments of the disclosure are described in detail, in the following order, with reference to the accompanying drawings.
1. Example Embodiment (an example of a thin-film transistor (TFT) in which a resin substrate having volume resistivity of equal to or greater than a predetermined value is used)
2. Application Examples (examples in each of which the TFT is applied to an electronic apparatus)
3. Modification Examples

Note that the following description is directed to illustrative examples of the technology and not to be construed as limiting to the technology. Further, factors including, without limitation, arrangement, dimensions, and a dimensional ratio of elements illustrated in each drawing are illustrative only and not to be construed as limiting to the technology.

### 1. Example Embodiment

### [Configuration]

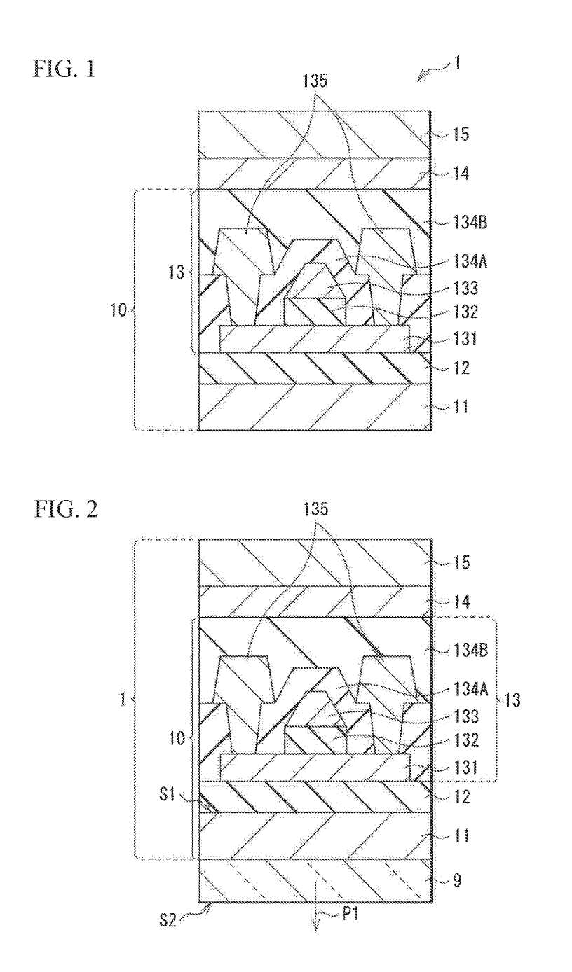

FIG. 1 is a schematic cross-sectional view of an example of an overall configuration of a display unit, referred to as a display unit 1, according to an embodiment of the disclosure. The display unit 1 serves as a flexible device according to one embodiment, and may be, for example, an electro-luminescence (EL) display unit. The display unit 1 may have a configuration in which a display element layer 14 and a protection layer 15 are provided in this order on a thin-film transistor, referred to as a thin-film transistor 10, according to an embodiment of the disclosure. The thin-film transistor 10 may include an insulating film 12 and a TFT (thin-film transistor) layer 13 in this order on a flexible substrate 11, for example. The insulating film 12 and the TFT layer 13 may be provided on a surface of the flexible substrate 11. The term “on” as used herein encompasses the term “above”.

The flexible substrate 11 may be made of a resin material such as polyethylene terephthalate (PET), polyimide (PI), polycarbonate (PC), polyethylene naphtalate (PEN), polyamide (PA), and polyethersulfone (PES). This means that the flexible substrate 11 may be configured by a resin substrate or a plastic substrate, for example. Preferred but non-limiting examples of the resin material may include a polyimide-based resin material. The flexible substrate 11 may correspond to a “resin substrate” according to one specific but non-limiting embodiment of the disclosure.

The insulating film 12 may be so provided as to be in contact with a bottom surface of a later-described semiconductor layer 131 in the TFT layer 13. The insulating film 12 may serve to provide a favorable interface between the insulating film 12 and the semiconductor layer 131, for example. The insulating film 12 may be one of a single-layer film and a multi-layered film each containing one or more of materials such as a silicon oxide (SiOₓ), a silicon nitride (SiN), a silicon oxynitride (SiON), and phosphorus(P)-doped SiO, for example. Alternatively, the insulating film 12 may contain an aluminum oxide (Al₂O₃), for example. The insulating film 12 may be thus configured by an inorganic insulating film, for example. The insulating film 12 may have a thickness in an example range from 200 nm to 1000 nm.

The TFT layer 13 may serve as a layer that configures the thin-film transistor 10. The thin-film transistor 10 may be a top-gate thin-film transistor, for example. The TFT layer 13 may include the semiconductor layer 131 in a selective region on the insulating film 12. A gate electrode 133 may be provided on the semiconductor layer 131 with a gate insulating film 132 in between. An interlayer insulating film 134A may be so provided as to cover the semiconductor layer 131, the gate insulating film 132, and the gate electrode 133. The interlayer insulating film 134A may have a contact hole in a region that is opposed to a part of the semiconductor layer 131. A source-drain electrode 135 may be so provided, as a pair of electrodes, on the interlayer insulating film 134A that the contact hole is filled with the source-drain electrode 135. An interlayer insulating film 134B may be so provided as to cover the interlayer insulating film 134A and the source-drain electrode 135.

The semiconductor layer 131 may be provided on the insulating film 12 to have a pattern. The semiconductor layer 131 may include a channel region or an “active layer” in a region that is opposed to the gate electrode 133. The semiconductor layer 131 may be made of an oxide semiconductor that contains, as a major component, an oxide of one or more of elements such as indium (In), gallium (Ga), zinc (Zn), tin (Sn), titanium (Ti), and niobium (Nb), for example. Specific but non-limiting examples of the oxide semiconductor may include an indium-tin-zinc oxide (ITZO), an indium-gallium-zinc oxide (IGZO: InGaZnO), a zinc oxide (ZnO), an indium-zinc oxide (IZO), an indium-gallium oxide (IGO), an indium-tin oxide (ITO), and an indium oxide (InO). Alternatively, the semiconductor layer 131 may be made of a material such as low-temperature polysilicon (LTPS) and amorphous silicon (a-Si), for example.

The gate insulating film 132 may be a single-layer film that is made of one of materials such as a silicon oxide (SiOₓ), a silicon nitride (SiNₓ), a silicon oxynitride (SiON), and an aluminum oxide (AlOₓ), for example. Alternatively, the gate insulating film 132 may be a multi-layered film that includes two or more of the foregoing materials, for example.

The gate electrode 133 may control a carrier density in the semiconductor layer 131 by means of a gate voltage that is applied to the gate electrode 133. The gate electrode 133 may also serve as a wiring line that supplies a potential. The gate electrode 133 may be made of a simple substance that contains one of materials such as titanium (Ti), tungsten (W), tantalum (Ta), aluminum (Al), molybdenum (Mo), silver (Ag), neodymium (Nd), and copper (Cu), for example. Alternatively, the gate electrode 133 may be made of an alloy that includes one of the foregoing materials, for example. The gate electrode 133 may be made of a compound that includes one or more of the foregoing materials, or configured by a multi-layered film that includes two or more of the foregoing materials, for example. The gate electrode 133 may be configured by a transparent electrically-conductive film such as a film of ITO, for example.

The interlayer insulating films 134A and 134B each may be made of an organic material such as an acrylic-based resin, polyimide (PI), and a novolac-based resin. Alternatively, the interlayer insulating film 134A may be made of an inorganic material such as a silicon oxide, a silicon nitride, a silicon oxynitride, and an aluminum oxide.

One of the electrodes of the source-drain electrode 135 may serve as a source of the thin-film transistor 10, while the other of the electrodes of the source-drain electrode 135 may serve as a drain of the thin-film transistor 10. The source-drain electrode 135 may be configured by a metal or a transparent conductive film similar to any of the foregoing materials given as examples of the material that forms the gate electrode 133. It is preferable, without limitation, that a material having a good electric conductivity be selected for the source-drain electrode 135.

The display element layer 14 may include a plurality of pixels. The display element layer 14 may also include a display element or a “light-emitting element” driven by the thin-film transistor 10 to perform display. Non-limiting examples of the display element may include an organic EL display element and a liquid crystal display element. In one embodiment where the display element is the organic EL element, the organic EL element may include an anode electrode, an organic electroluminescent layer, and a cathode electrode in order from the TFT layer 13, for example. The anode electrode, the organic electroluminescent layer, and the cathode electrode may respectively serve as a “first electrode”, a “display function layer”, and a “second electrode”. For example, the anode electrode may be coupled to the source-drain electrode 135. The cathode electrode may receive a supply of cathode potential, for example, via a wiring line. The cathode potential may be a potential common to each of the pixels.

The protection layer 15 may protect the display element layer 14 from outside factors. The protection layer 15 may be made of an inorganic material such as a silicon oxide (SiOₓ), a silicon nitride (SiNₓ), and a silicon oxynitride (SiON). Alternatively, the protection layer 15 may be made of an organic material.

Referring, for example, to FIG. 2, a support substrate 9 may be attached to the flexible substrate 11 as described later in greater detail upon manufacturing of the display unit 1. The support substrate 9 may be a glass substrate or any other suitable substrate. More specifically, the support substrate 9 may have a front surface S1 serving as a first surface and a back surface S2 serving as a second surface that are opposed to each other, and the front surface S1 of the support substrate 9 may be attached to a back surface of the flexible substrate 11.

The support substrate 9 may be detached from the flexible substrate 11 as denoted by arrow P1 of FIG. 2, after each of the layers including the insulating film 12, the TFT layer 13, the display element layer 14, and the protection layer 15 are formed on the flexible substrate 11. In one specific but non-limiting example, an interface between the support substrate 9 and the flexible substrate 11, or a region in the vicinity of the interface, may be irradiated with laser light to cause the support substrate 9 to be detached from the flexible substrate 11.

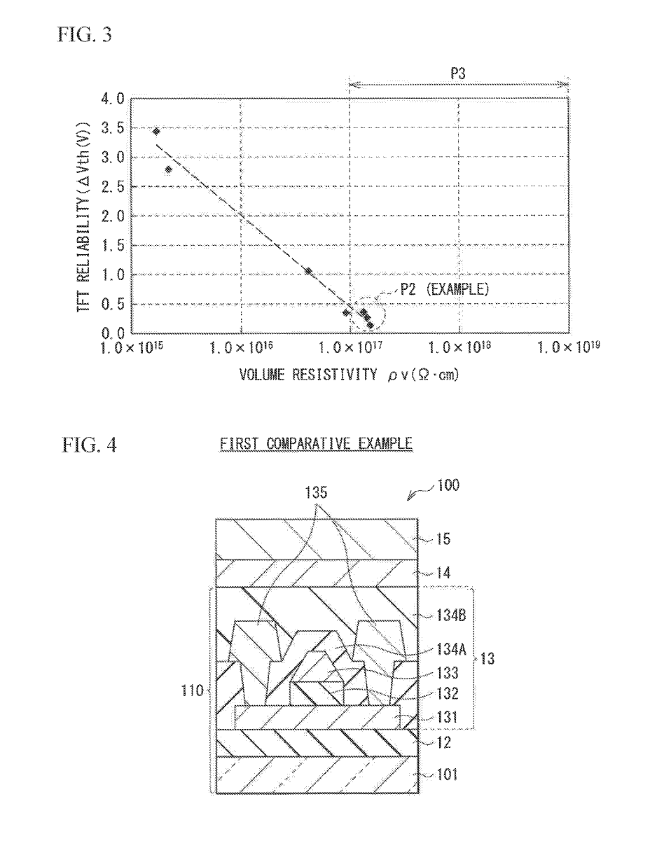

Referring, for example, to FIG. 3, the flexible substrate 11 according to the present example embodiment has volume resistivity ρv of equal to or greater than a predetermined value. FIG. 3 is a characteristic diagram illustrating an example of a relationship between the volume resistivity ρv of the flexible substrate 11 which was configured by the resin substrate and a threshold voltage variation ΔVth in the thin-film transistor 10. The threshold voltage variation ΔVth is an indicator of reliability of the thin-film transistor 10, i.e., an indicator of TFT reliability.

For example, as denoted by arrow P2 of FIG. 3 according to Example, the flexible substrate 11 configured by the resin substrate according to the present example embodiment may have the volume resistivity ρv of equal to or greater than 1×10¹⁷ [Ω·cm], i.e., may satisfy ρv≧1×10¹⁷ [Ω·cm]. Preferably, the flexible substrate 11 may have the volume resistivity ρv in a range from 1×10¹⁷ [Ω·cm] to 1×10¹⁹ [Ω·cm], i.e., may have the volume resistivity ρv that satisfies 1×10¹⁷ [Ω·cm]≦ρv≦1×10¹⁹ [Ω·cm], as illustrated by a range denoted by arrow P3 of FIG. 3, for example. The term “volume resistivity ρv” as used herein refers to a value of electrical resistivity per unit volume of the flexible substrate 11, which is equivalent to a level of difficulty that a current flows in a thickness direction of the flexible substrate 11.

One reason why the volume resistivity ρv of equal to or greater than 1×10¹⁷ [Ω·cm] is desirable is that this increases electrical insulation of the flexible substrate 11 configured by the resin substrate as described later in greater detail. In other words, this allows a value of the threshold voltage variation ΔVth to be equal to or less than 0.5 [V]. Further, one reason why the volume resistivity ρv of equal to or less than 1×10¹⁹ [Ω·cm] is desirable is that it is extremely difficult to fabricate a resin substrate having the volume resistivity ρv that exceeds the value of 1×10¹⁹ [Ω·cm].

### [Manufacturing Method]

The foregoing display unit 1 may be manufactured in the following example manner.

First, the flexible substrate 11 may be prepared that has the volume resistivity ρv in the above-described range. More specifically, a resin material that allows the flexible substrate 11 to have such volume resistivity ρv is used to form the flexible substrate 11.

Thereafter, the front surface S1 of the support substrate 9 may be attached to the back surface of the thus-formed flexible substrate 11. Non-limiting examples of a method of attaching the front surface S1 to the back surface of the flexible substrate 11 may include thermal setting and bonding. The thermal setting may involve application of varnish or any other coating material on the support substrate 9. The bonding may involve utilization of a bonding layer or any other element that allows for bonding. Non-limiting examples of a constituent material of the bonding layer may include siloxane.

After the attachment of the support substrate 9, the insulating film 12 made of any of the foregoing materials and having the thickness exemplified above may be formed on the surface of the flexible substrate 11. The insulating film 12 may be formed using a method such as chemical vapor deposition (CVD).

Thereafter, element layers including the TFT layer 13 and the display element layer 14 may be formed on a surface of the insulating film 12.

In forming the element layers, the TFT layer 13 may be formed on the insulating film 12 in the beginning. More specifically, first, the semiconductor layer 131 made of any of the foregoing materials, such as an oxide semiconductor, may be formed on the insulating film 12 using a method such as sputtering, following which the thus-formed semiconductor layer 131 may be patterned into a predetermined shape using methods such as photolithography and etching. Thereafter, the gate insulating film 132 made of any of the foregoing materials may be formed using a method such as CVD. Thereafter, the gate electrode 133 made of any of the foregoing materials may be formed, in a pattern, on the gate insulating film 132, following which the thus-formed gate electrode 133 may be used as a mask to perform patterning of the gate insulating film 132 by means of etching of the gate insulating film 132. Thereafter, the interlayer insulating film 134A may be formed, following which the contact hole may be formed in the region opposed to a part of the semiconductor layer 131. Thereafter, the source-drain electrode 135 as the pair of electrodes made of any of the foregoing metal materials may be so formed on the interlayer insulating film 134A that the contact hole is filled with the source-drain electrode 135. Thereafter, the interlayer insulating film 134B may be so formed as to cover the interlayer insulating film 134A and the source-drain electrode 135. This may form the TFT layer 13.

Thereafter, the display element layer 14 may be formed on the TFT layer 13. For example, in one embodiment where the display element layer 14 includes the organic EL element, the display element layer 14 that includes the anode electrode, the organic electroluminescent layer, and the cathode electrode may be formed on the TFT layer 13.

Thereafter, the protection layer 15 made of any of the foregoing materials may be formed on the display element layer 14 using a method such as CVD.

Thereafter, the support substrate 9 may be detached from the flexible substrate 11 as denoted by the arrow P1 of FIG. 2, for example. More specifically, for example, the interface between the support substrate 9 and the flexible substrate 11 or a region in the vicinity of the interface, such as the bonding layer, may be irradiated with the laser light from the back surface S2 of the support substrate 9 to cause the support substrate 9 to be detached from the flexible substrate 11. The detachment of the support substrate 9 from the flexible substrate 11 by means of the laser light irradiation may be derived from an example mechanism in which the laser light irradiation dissipates or decreases binding force between atoms or molecules structuring the flexible substrate 11, or dissipates or decreases binding force between atoms or molecules of a substance structuring the bonding layer, thereby leading to in-layer delamination or interfacial delamination.

The foregoing example processes may complete the display unit 1 illustrated in FIG. 1.

### [Workings and Effect]

### [Basic Operation]

In the display unit 1 according to the present example embodiment, each of the pixels provided in the display element layer 14 may be driven, to perform display, based on an image signal that may be supplied from outside. As a result, an image is displayed. Upon performing the image display, the TFT layer 13 may involve driving of the thin-film transistor 10 on a pixel-by-pixel basis in response to a supplied voltage, for example. More specifically, when a voltage that is equal to or greater than a threshold voltage is supplied to any thin-film transistor 10, the semiconductor layer 131 may be activated, i.e., the semiconductor layer 131 may form a channel, causing a current to flow between the pair of electrodes of the source-drain electrode 135 of the thin-film transistor 10 accordingly. The display unit 1 may thus perform the image display by utilizing the voltage driving performed on the thin-film transistors 10.

### Comparative Example

FIG. 4 is a schematic cross-sectional view of an example of an overall configuration of a display unit, referred to as a display unit 100, according to a first comparative example. The display unit 100 serves as a flexible device. The display unit 100 according to the first comparative example may have a configuration in which the display element layer 14 and the protection layer 15 are provided in this order on a thin-film transistor, referred to as a thin-film transistor 110, according to the first comparative example. The thin-film transistor 110 according to the first comparative example is basically similar in configuration to the thin-film transistor 10 according to the example embodiment, with the exception that a flexible substrate 101 is provided instead of the flexible substrate 11 as described below.

The flexible substrate 101 is configured by a glass substrate unlike the flexible substrate 11 that may be made of the resin substrate. This means that the flexible substrate 101 is made of a glass material instead of the resin material.

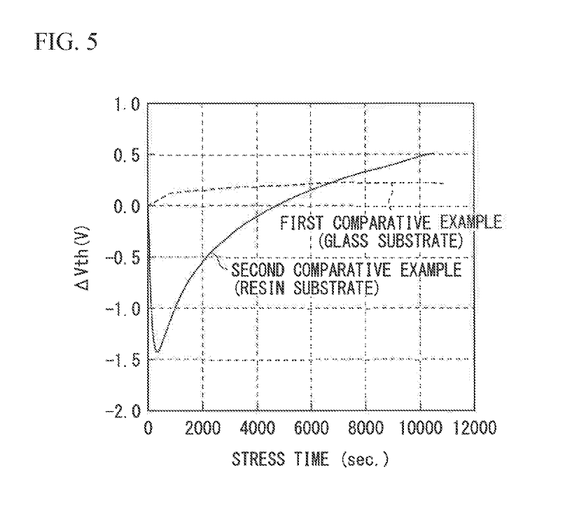

It can be appreciated from an example illustrated in FIG. 5 that the thin-film transistor 110 according to the first comparative example involved the threshold voltage variation ΔVth which was substantially 0 (zero) even when stress time, i.e., test time, upon a reliability test was increased. In other words, the thin-film transistor 110 according to the first comparative example had the threshold voltage which was substantially constant irrespective of the length of the stress time. Note that the reliability test according to the example illustrated in FIG. 5 was conducted under the conditions in which the gate voltage Vg was 15 V, the drain voltage Vd was 15 V, the source voltage Vs was 0 V, and an ambient temperature was 50 degrees centigrade.

A thin-film transistor according to a second comparative example illustrated in FIG. 5 had a flexible substrate configured by a resin substrate as with the flexible substrate 11 according to the example embodiment. However, the flexible substrate configured by the resin substrate according to the second comparative example had the volume resistivity ρv of less than 1×10¹⁷ [Ω·cm] unlike the flexible substrate 11 according to the example embodiment (see FIG. 3).

It can be appreciated from FIG. 5 that the thin-film transistor according to the second comparative example involved the threshold voltage variation ΔVth which was significantly increased with an increase in the stress time upon the reliability test as compared with the first comparative example where the glass substrate was used. More specifically, in the example illustrated in FIG. 5, the threshold voltage variation ΔVth was at a negative value, i.e., the threshold voltage varied in a minus direction, up to a point where the stress time was about 5000 seconds (denoted as “sec”), raising a possibility of generation of a leakage current in the thin-film transistor. The threshold voltage variation ΔVth was at a positive value, i.e., the threshold voltage varied in a plus direction, after the stress time became greater than about 5000 seconds, contrary to the threshold voltage variation ΔVth which was at the negative value up to the point where the stress time was about 5000 seconds.

Consequently, the second comparative example in which the resin substrate was used may possibly involve an increased variation in the threshold voltage of the thin-film transistor and its consequential decrease in reliability, as compared with the first comparative example in which the glass substrate was used.

### Example Embodiment

In contrast, the thin-film transistor 10 according to the example embodiment included the flexible substrate 11 that was configured by the resin substrate and that had the volume resistivity ρv of equal to or greater than 1×10¹⁷ [Ω·cm], i.e., satisfied ρv≧1×10¹⁷ [Ω·cm], as illustrated by way of example in FIG. 3 according to Example. Preferably, the flexible substrate 11 had the volume resistivity ρv in a range from 1×10¹⁷ [Ω·cm] to 1×10¹⁹ [Ω·cm], i.e., had the volume resistivity ρv that satisfied 1×10¹⁷ [Ω·cm]≦ρv≦1×10¹⁹ [Ω·cm], as illustrated by the range that is denoted by arrow P3 of FIG. 3, for example.

This increased the electrical insulation of the resin substrate, i.e., the flexible substrate 11, as compared with the second comparative example, which suppressed the variation in the threshold voltage of the thin-film transistor 10 as illustrated by way of example in the FIG. 3 according to the Example. More specifically, it can be appreciated from the Example illustrated in FIG. 3 that the threshold voltage variation ΔVth was suppressed to less than 0.5 V, and that the threshold voltage variation ΔVth was ensured which was equal to that of the first comparative example (see FIG. 5) where the glass substrate, i.e., the flexible substrate 101, was used.

Such workings according to the example embodiment are presumably derived from the following example mechanism. More in detail, in a typical top-gate thin-film transistor in which a resin substrate is used, electric charges present in the resin substrate may gather near an interface between the resin substrate and an insulating film located on the resin substrate to possibly function as a pseudo back gate in the thin-film transistor. The thin-film transistor 10 according to the example embodiment thus increases the volume resistivity ρv to increase the electrical insulation of the resin substrate, i.e., the flexible substrate 11 accordingly. This allows the resin substrate, i.e., the flexible substrate 11, to have the electrical insulation that is close to that of, for example, the glass substrate, i.e., the flexible substrate 101 according to the first comparative example. In other words, this makes the electric charges described above hardly generated. As a result, the electric charges are presumably prevented from functioning as the pseudo back gate and the variation in the threshold voltage is presumably suppressed accordingly.

Note that suppressing the variation in the threshold voltage is particularly advantageous especially for the thin-film transistor in which, for example, the foregoing oxide semiconductor is used for the semiconductor layer or the “active layer” of the thin-film transistor, in that the electric potential tends to be generated easily in the thin-film transistor that uses the oxide semiconductor for the active layer.

According to the foregoing example embodiment, the thin-film transistor 10 includes the flexible substrate 11 that is configured by the resin substrate and that has the volume resistivity ρv of equal to or greater than 1×10¹⁷ [Ω·cm]. This makes it possible to suppress the variation in the threshold voltage of the thin-film transistor 10. Hence, it is possible to increase reliability of the thin-film transistor 10 that uses the resin substrate. In other words, the thin-film transistor 10 that uses the resin substrate is also able to ensure reliability equal to that of a thin-film transistor that uses a glass substrate, such as the glass substrate according to the first comparative example.

In one embodiment where the display unit 1 that uses the thin-film transistor 10 is configured by, for example, an organic EL display unit, suppressing the variation in the threshold voltage is particularly advantageous in that the organic EL display unit is typically low in tolerance to the variation in the threshold voltage of a thin-film transistor that configures a drive circuit. In other words, it is also possible for the display unit configured by the organic EL display unit to achieve a large effect of suppressing the variation in the threshold voltage, in view of the organic EL display unit which is generally based on current driving and thus variation in light-emission luminance attributed to the variation in the threshold voltage is large.

### 2. Application Examples

A description is given next of examples in each of which the thin-film transistor 10 according to the foregoing example embodiment is applied to an electronic apparatus.

First, a description is given of an example of a block configuration of each of a display unit and an imaging unit. The display unit and the imaging unit each may serve as one specific but non-limiting example of the flexible device according to one embodiment of the disclosure.

### [Example of Block Configuration of Display Unit 1]

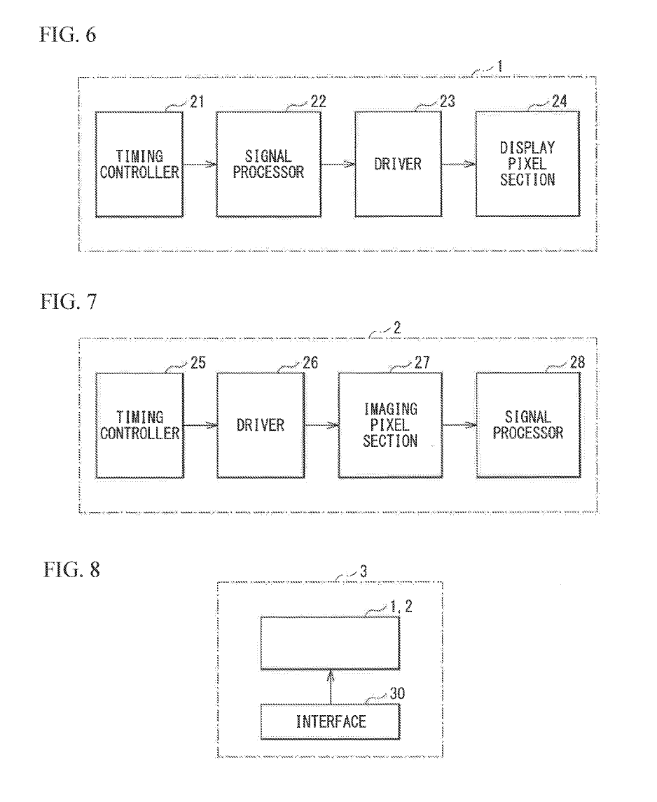

FIG. 6 is a block diagram schematically illustrating an example of an overall configuration of the display unit 1 that serves as one example of the flexible device. The display unit 1 may display, as an image, a picture signal received from the outside of the display unit 1 or generated inside of the display unit 1. The display unit 1 may be applied not only to an organic EL display as described above but also a liquid crystal display or any other display. The display unit 1 may include a timing controller 21, a signal processor 22, a driver 23, and a display pixel section 24.

The timing controller 21 may include a timing generator that generates various timing signals, i.e., control signals. The timing controller 21 may control driving of the signal processor 22, etc., on the basis of the various timing signals.

The signal processor 22 may perform a predetermined correction on, for example, the digital picture signal supplied from the outside, and output the thus-obtained picture signal to the driver 23.

The driver 23 may include circuits including a scanning line driving circuit and a signal line driving circuit. The driver 23 may drive each pixel provided in the display pixel section 24 through various control lines.

The display pixel section 24 may include a display device and a pixel circuit designed to drive the display device on a pixel basis. The display device may be an organic EL device, a liquid crystal display device, or any other device directed to image display. The display device is, in other words, the display element layer 14. The thin-film transistor 10 including the TFT layer 13 may be used for various circuits provided in the driver 23, various circuits structuring a part of the display pixel section 24, or both.

### [Example of Block Configuration of Imaging Unit 2]

The example embodiment has been described by referring to the display unit 1 as one specific but non-limiting example of the flexible device according to one embodiment of the disclosure. More specifically, the example embodiment has been described by referring to the display unit 1 as one application example of the thin-film transistor 10. In an alternative embodiment, the flexible device may be configured by any other unit besides the display unit 1, such as an imaging unit. In other words, the thin-film transistor 10 may be used for any other unit, such as the imaging unit, besides the display unit 1.

FIG. 7 is a block diagram schematically illustrating an example of an overall configuration of an imaging unit 2 that serves as one example of the flexible device. The imaging unit 2 may be a solid-state imaging unit that obtains an image as an electric signal, for example. The imaging unit 2 may include a charge-coupled device (CCD) image sensor, a complementary metal oxide semiconductor (CMOS) image sensor, or any other suitable image sensor. The imaging unit 2 may include a timing controller 25, a driver 26, an imaging pixel section 27, and a signal processor 28.

The timing controller 25 may include a timing generator that generates various timing signals, i.e., control signals. The timing controller 25 may control driving of the driver 26, on the basis of the various timing signals.

The driver 26 may include circuits including a row selection circuit, an analog to digital (AD) conversion circuit, and a horizontal transfer scanning circuit. The driver 26 may perform driving that reads out signals from respective pixels provided in the imaging pixel section 27 through various control lines.

The imaging pixel section 27 may include an imaging device, i.e., a photoelectric conversion device, and a pixel circuit designed to read out the signals. The imaging device may be a photodiode or any other device directed to imaging. Besides the device that detects visible light, the imaging device may be any device that detects infrared light, ultraviolet light, radiation such as X rays, or any other suitable factor, either directly or indirectly.

The signal processor 28 may apply various signal processes to the signals obtained from the imaging pixel section 27. The thin-film transistor 10 including the TFT layer 13 may be used for various circuits provided in the driver 26, various circuits structuring a part of the imaging pixel section 27, or both.

### [Example of Configuration of Electronic Apparatus]

The flexible device described in the foregoing example embodiment, such as the display unit 1 and the imaging unit 2 each including the thin-film transistor 10, may be applied to any of various electronic apparatuses.

FIG. 8 is a block diagram illustrating an electronic apparatus, referred to as an electronic apparatus 3, that includes one of the display unit 1 illustrated in FIG. 6 and the imaging unit 2 illustrated in FIG. 7 according to an application example. Non-limiting examples of the electronic apparatus 3 may include a television, a personal computer (PC), a smartphone, a tablet PC, a mobile phone, a digital still camera, a digital video camera, and any other suitable device that includes a thin-film transistor.

The electronic apparatus 3 may include an interface 30 and one of the display unit 1 and the imaging unit 2 described above. The interface 30 may be an input section that receives various signals, a power supply, etc., from the outside. The interface 30 may include a user interface such as a touch panel, a keyboard, and operation buttons.

### 3. Modification Examples

Although a technique of the disclosure has been described by way of example with reference to the example embodiment and the application examples, the technology is not limited thereto but may be modified in a wide variety of ways.

For example, factors such as a material and a thickness of each layer exemplified in the foregoing example embodiment and the application examples are illustrative and non-limiting. Any other material, any other thickness, and any other factor may be adopted besides those described above. It is not essential for the foregoing thin-film transistor to include all of the layers described above. Alternatively, the foregoing thin-film transistor may further include any other layer in addition to the layers described above.

The example embodiment and the application examples have been described with specific reference to a range of magnitude of the volume resistivity ρv of the flexible substrate 11, i.e., the resin substrate. The volume resistivity ρv of the flexible substrate 11, however, is not limited thereto, and may be in any other range.

Furthermore, the technology encompasses any possible combination of some or all of the various examples described herein and incorporated herein.

Further, effects described herein are illustrative and non-limiting. Effects achieved by the technology may be those that are different from the above-described effects, or may include other effects in addition to those described above.

It is possible to achieve at least the following configurations from the above-described example embodiments of the disclosure.
(1) A thin-film transistor including:

a resin substrate having flexibility, and having volume resistivity of equal to or greater than 1×10¹⁷ Ω·cm; and

a thin-film transistor layer provided on the resin substrate.
(2) The thin-film transistor according to (1), wherein the resin substrate has the volume resistivity that is in a range from 1×10¹⁷ Ω·cm to 1×10¹⁹ Ω·cm.
(3) The thin-film transistor according to (1) or (2), wherein the thin-film transistor layer includes an oxide semiconductor layer.
(4) The thin-film transistor according to (3), wherein the thin-film transistor is a top-gate thin-film transistor in which the thin-film transistor layer includes a gate insulating film and a gate electrode in this order on the oxide semiconductor layer.
(5) The thin-film transistor according to any one of (1) to (4), wherein the resin substrate is made of a polyimide-based resin material.
(6) A display unit with a thin-film transistor and a display element layer, the thin-film transistor including:

a resin substrate having flexibility, and having volume resistivity of equal to or greater than 1×10¹⁷ Ω·cm; and

a thin-film transistor layer provided on the resin substrate.
(7) The display unit according to (6), wherein the display unit is an organic electroluminescence display unit in which the display element layer includes an organic electroluminescence element.
(8) An electronic apparatus with one of a display unit and an imaging unit, the display unit and the imaging unit each being provided with a thin-film transistor, the thin-film transistor including:

a resin substrate having flexibility, and having volume resistivity of equal to or greater than 1×10¹⁷ Ω·cm; and

a thin-film transistor layer provided on the resin substrate.

In the thin-film transistor, the display unit, and the electronic apparatus according to respective embodiments of the disclosure, the resin substrate has the flexibility and has the volume resistivity of equal to or greater than 1×10¹⁷ Ω·cm. This increases electrical insulation of the resin substrate, suppressing variation in threshold voltage of the thin-film transistor.

The thin-film transistor, the display unit, and the electronic apparatus according to the respective embodiments of the disclosure includes the resin substrate that has the flexibility and the volume resistivity of equal to or greater than 1×10¹⁷ Ω·cm. This makes it possible to suppress the variation in the threshold voltage of the thin-film transistor. Hence, it is possible to increase reliability.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably”, “preferred” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” or “approximately” as used herein can allow for a degree of variability in a value or range. Moreover, no element or component in this disclosure is intended to be dedicated to the public regardless of whether the element or component is explicitly recited in the following claims.

What is claimed is:

1. A thin-film transistor comprising:
a resin substrate having flexibility, and having volume resistivity of equal to or greater than 1×10¹⁷ Ω·cm; and
a thin-film transistor layer provided on the resin substrate.

2. The thin-film transistor according to claim 1, wherein the resin substrate has the volume resistivity that is in a range from 1×10¹⁷ Ω·cm to 1×10¹⁹ Ω·cm.

3. The thin-film transistor according to claim 1, wherein the thin-film transistor layer includes an oxide semiconductor layer.

4. The thin-film transistor according to claim 3, wherein the thin-film transistor comprises a top-gate thin-film transistor in which the thin-film transistor layer includes a gate insulating film and a gate electrode in this order on the oxide semiconductor layer.

5. The thin-film transistor according to claim 1, wherein the resin substrate is made of a polyimide-based resin material.

6. A display unit with a thin-film transistor and a display element layer, the thin-film transistor comprising:
a resin substrate having flexibility, and having volume resistivity of equal to or greater than 1×10¹⁷ Ω·cm; and
a thin-film transistor layer provided on the resin substrate.

7. The display unit according to claim 6, wherein the display unit comprises an organic electroluminescence display unit in which the display element layer includes an organic electroluminescence element.

8. An electronic apparatus with one of a display unit and an imaging unit, the display unit and the imaging unit each being provided with a thin-film transistor, the thin-film transistor comprising:
a resin substrate having flexibility, and having volume resistivity of equal to or greater than 1×10¹⁷ Ω·cm; and
a thin-film transistor layer provided on the resin substrate.
